(19) United States
(12) Patent Application Publication
(10) Pub. No.: US 2009/0057763 A1
(43) Pub. Date: Mar. 5, 2009

(54) SEMICONDUCTOR MEMORY DEVICE AND MANUFACTURING METHOD THEREOF

(75) Inventor: Yoshihiro MINAMI, Yokosuka-Shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 12/195,861

(22) Filed: Aug. 21, 2008

(30) Foreign Application Priority Data
Aug. 31, 2007 (JP) 2007-225374

(51) Int. Cl. H01L 29/786; H01L 21/28

(52) U.S. Cl. 257/347; 438/586; 257/E29.273; 257/E21.177

(57) ABSTRACT

This disclosure concerns a semiconductor memory device including an insulating film; a semiconductor layer provided on the insulating film; a source provided in the semiconductor layer; a drain provided in the semiconductor layer; a floating body provided between the source and the drain and being in an electrically floating state, carriers being accumulated in or emitted from the floating body to store data; a gate dielectric film provided on the floating body; a gate electrode provided on the gate dielectric film; a source and drain insulating film provided on the source and the drain, the source and drain insulating film being thinner than the gate dielectric film; and a silicide layer provided on the source and drain insulating film.

### CROSS-REFERENCE TO RELATED APPLICATIONS

This application is based upon and claims the benefit of priority from the prior Japanese Patent Application No. 2007-225374, filed on Aug. 31, 2007, the entire contents of which are incorporated herein by reference.

### BACKGROUND OF THE INVENTION

1. Field of the Invention

The present invention relates to a semiconductor memory device and a manufacturing method thereof.

2. Related Art

In recent years, there is known an FBC (Floating Body Cell) memory device as a semiconductor memory device expected to replace a 1T (Transistor)-1C (Capacitor) DRAM. The FBC memory device includes FETs (Field Effect Transistors) each including a floating body (hereinafter, also “body”) on an SOI (Silicon On Insulator) substrate. The FBC memory device stores data “1” or data “0” in each FET according to the number of majority carriers accumulated in the body of the FET.

A configuration in which no element isolation region is present between a plurality of cell transistors adjacent in a bit line direction is proposed to realize higher integration of the FBC memory device. With this configuration, a source or a drain is shared among a plurality of cell transistors adjacent in the bit line direction.

However, if the drain or source is shared among the memory cells, holes from the body of each of the memory cells possibly pass through the drain or source and flow into the adjacent memory cells. This phenomenon is called “bipolar disturbance”.

Measures for making an SOI layer thin and forming a silicide layer on sources and drains are proposed so as to realize the higher integration of the FBC memory device and, at the same time, to suppress the bipolar disturbance. However, it is difficult to control a thickness of the silicide layer with high accuracy. Due to this, the silicide layer often reaches a BOX layer in a region in which the source or the drain is present (“source or drain region”). If the silicide layer penetrates through the BOX layer in the source or drain region near the body, in particular, an area of a silicide-silicon interface becomes quite small. Generally, the silicide-silicon interface is higher in resistance than an interior of the silicon and an interior of the silicide. Due to this, if the silicide layer penetrates through the BOX layer, a contact resistance increases in the source or drain. Conversely, if the silicide layer is thin and the SOI layer below the source or drain is thick, it cannot be expected to produce a bipolar disturbance suppression effect.

### SUMMARY OF THE INVENTION

A semiconductor memory device according to an embodiment of the present invention comprises an insulating film; a semiconductor layer provided on the insulating film; a source provided in the semiconductor layer; a drain provided in the semiconductor layer; a floating body provided between the source and the drain and being in an electrically floating state, carriers being accumulated in or emitted from the floating body to store data; a gate dielectric film provided on the floating body; a gate electrode provided on the gate dielectric film; a source and drain insulating film provided on the source and the drain, the source and drain insulating film being thinner than the gate dielectric film; and a silicide layer provided on the source and drain insulating film.

A method of manufacturing a semiconductor memory device according to an embodiment of the present invention comprises forming a gate dielectric film on a semiconductor layer provided on an insulating film; forming a gate electrode on the gate dielectric film; forming a sidewall insulating film on a side surface of the gate electrode, and forming a source and drain insulating film on a surface of the semiconductor layer not covered with the gate electrode and the sidewall insulating film, the source and drain insulating film being thinner than the gate dielectric film; depositing a silicon film on the source and drain insulating film; removing the silicon film on the gate electrode; depositing a metal film on the silicon film; and siliciding the silicon film by reacting the silicon film with the metal film.

### BRIEF DESCRIPTION OF THE DRAWINGS

FIG. 1 is a partial plan view of a memory cell array of an FBC memory device according to a first embodiment of the present invention;

FIG. 2 is a cross-sectional view taken along a line I-I of FIG. 1;

FIGS. 3 to 8 are cross-sectional views showing the method of manufacturing the FBC memory device according to the first embodiment;

FIG. 9 is a cross-sectional view showing a method of manufacturing an FBC memory device according to a modification of the first embodiment of the present invention;

FIG. 10 is a cross-sectional view of an FBC memory device according to a second embodiment of the present invention;

FIGS. 11 and 12 are cross-sectional views showing a method of manufacturing the FBC memory device according to the second embodiment;

FIG. 13 is a cross-sectional view of an FBC memory device according to a third embodiment of the present invention;

FIGS. 14 and 15 are cross-sectional view showing a method of manufacturing the FBC memory device according to the third embodiment; and

FIG. 16 is a cross-sectional view of an FBC memory device according to a fourth embodiment of the present invention.

### DETAILED DESCRIPTION OF THE INVENTION

Embodiments of the present invention will be explained below in detail with reference to the accompanying drawings. Note that the invention is not limited thereto.

### First Embodiment

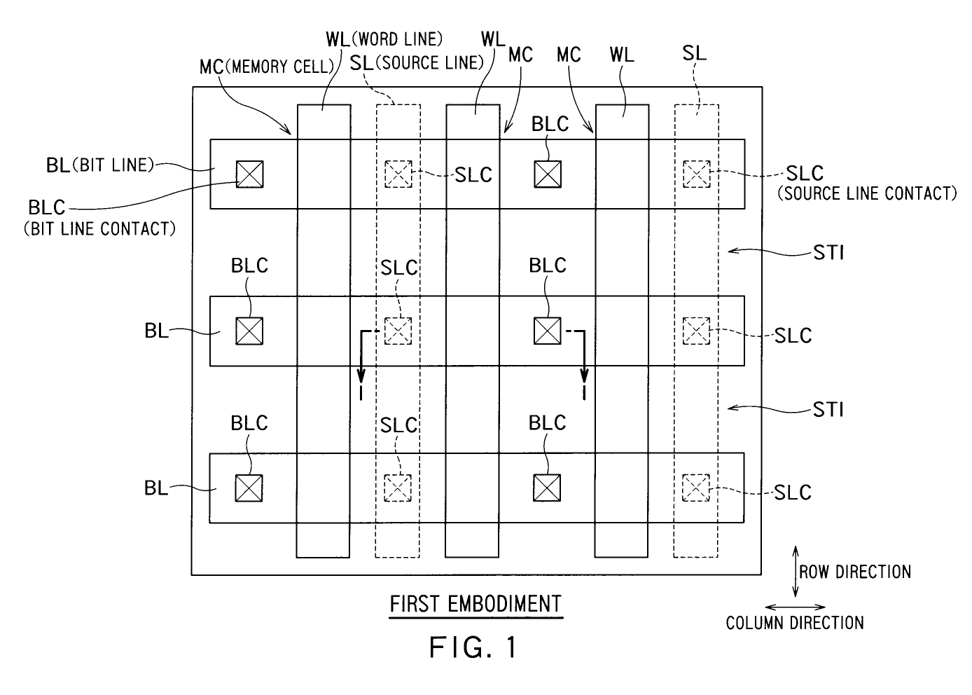

FIG. 1 is a partial plan view of a memory cell array of an FBC memory device according to a first embodiment of the present invention. The FBC memory device includes bit lines BLs extending in a column direction, word lines WLs extending in a row direction perpendicular to the column direction, and source lines SLs extending in the row direction similarly to the word lines WLs. SOI regions each serving as an active area are provided under the bit lines BLs to extend in the column direction similarly to the bit lines BLs. The SOI regions are formed into stripes similarly to the bit lines BLs. An STI is formed between two adjacent SOI regions. The word lines WLs and the source lines SLs are formed into stripes in a direction orthogonal to the bit lines BLs. Memory cells MCs are formed at crosspoints between the bit lines BLs and the word lines WLs, respectively.

Each bit line contact BLC electrically connects one bit line BL to a drain of each of the memory cells MCs. Presence of bit line contacts BLCs and source line contacts SLCs show that two memory cells MCs adjacent in the column direction, i.e., source-drain direction share one source or drain therebetween.

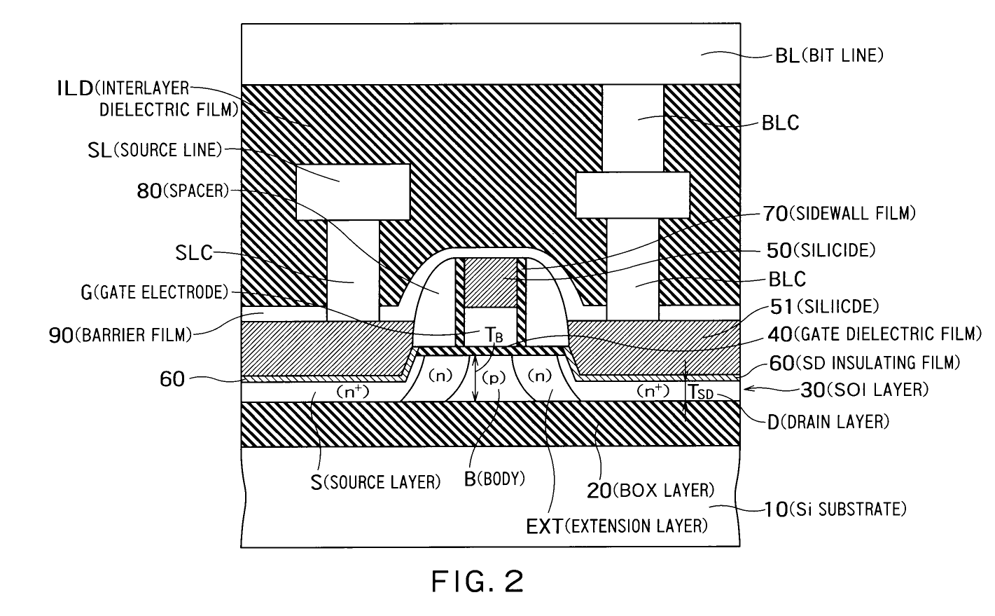

FIG. 2 is a cross-sectional view taken along a line I-I of FIG. 1. A cross section of one memory cell MC is shown in FIG. 2. The memory cell MC is formed on an SOI substrate configured to include a bulk silicon substrate 10, a BOX (Buried Oxide) layer 20, and an SOI layer 30. In the first embodiment, each memory cell MC is constituted by an n-MISFET (Metal-Insulator-Semiconductor Field-Effect Transistor).

A source layer S, a drain layer D, and a body B are provided in the SOI layer 30 formed on the BOX layer 20. The body B is provided between the source layer S and the drain layer D and is in an electrically floating state. Majority carriers are accumulated in or emitted from the body B to store data in the memory cell MC. The memory cell MC can thereby store binary data. Each of the source layer S and the drain layer D is an n-type diffusion layer. The body B is a p-type diffusion layer. An extension layer EXT extends from the source layer S or drain layer D to the body B. The extension layer EXT is provided to relax an electric field between the body B and the source layer S and that between the body B and the drain layer D. The extension layer EXT is an n-type diffusion layer lower in impurity concentration than the source layer S and the drain layer D.

A gate dielectric film 40 is provided on the body B and the extension layer EXT. The gate dielectric film 40 is, for example, a silicon oxide film, a silicon nitride film, a silicon oxynitride film or a hafnium-based high dielectric constant insulating film such as HfSiON. A gate electrode G is provided on the gate dielectric film 40. A silicide layer 50 is provided on the gate electrode G. The silicide layer 50 on the gate electrode G and the gate electrode G act as one word line WL. The gate electrode G is made of, for example, polysilicon. The silicide layer 50 is made of, for example, nickel silicide.

A source/drain insulating film (hereinafter, “SD insulating film”) 60 is provided on the source layer S and the drain layer D. The SD insulating film 60 is, for example, a silicon oxide film, a silicon nitride film, a silicon oxynitride film or a high dielectric constant insulating film. Examples of the high dielectric constant insulating film include HfSiO, HfSiON, Ta₂O₅, BaTiO₃, BaZrO₃, ZrO₂, HfO₂, and Al₂O₃. The SD insulating film 60 is formed to be thinner than the gate dielectric film 40 and functions as a tunnel insulating film. Namely, the SD insulating film 60 is so thin as to allow charges (electrons or holes) to tunnel between the source layer S and a silicide layer 51 on the source layer S and between the drain layer D and the silicide layer 51 on the drain layer D. The silicide layer 51 is provided on the SD insulating film 60 provided on the source layer S and the drain layer D.

A sidewall film 70 and a spacer 80 are formed on side surfaces of the gate electrode G and the silicide layer 50. A barrier film 90 covers up each memory cell MC that includes the source layer S, the drain layer D, the body B, the gate dielectric film 40, and the gate electrode G. The barrier film 90 is, for example, a silicon nitride film and functions as an etching stopper at the time of forming contact holes. An interlayer dielectric film ILD is provided on the barrier film 90. Bit line contacts BLCs and source line contacts SLCs are buried in the interlayer dielectric film ILD. The source lines SLs are formed on the source line contacts SLCs and the bit lines BLs are formed on the bit line contacts BLCs.

A thickness TSD of the SOI layer 30 in which the source layer S or the drain layer D is formed is made smaller than a thickness TB of the SOI layer 30 in which the body B is formed. By doing so, charges from the body B of one memory cell MC can be suppressed from flowing into the adjacent memory cell MC via the source layer S or the drain layer D. More specifically, if holes flow into the source layer S or the drain layer D from the body B, the holes tunnel through the SD insulating film 60 and flow to the silicide layer 51 because the source layer S and the drain layer L are thin. The holes or electrons once flowing to the silicide layer 51 flow to the source line SL or the bit line BL. This can suppress the bipolar disturbance. With views of suppression of the bipolar disturbance, the thickness TSD of the SOI layer 30 in which the source layer S or the drain layer D is formed is preferably smaller. For example, a thickness TSD of the SOI layer 30 is preferably smaller than 10 nm to suppress the bipolar disturbance.

It appears that the SD insulating film 60 is preferably absent in view of contact resistances of the source layer S and the drain layer D. However, by daring to provide the SD insulating film 60, it is advantageously possible to prevent the silicide layer 51 from penetrating through the source layer S or the drain layer D and to form the source layer S and the drain layer D to be thin at substantially uniform thickness. Namely, the SD insulating film 60 is intended to form the source layer S and the drain layer D as thin as possible and to have the uniform thickness.

By so making the thicknesses of the source layer S and the drain layer D uniform, an area by which the source layer S is adjacent to the silicide layer 51 and that by which the drain layer D is adjacent to the silicide layer 51 can be kept wide. This can, therefore, ensure suppressing the contact resistances from rising due to the penetration of the silicide layer 51 as seen in the conventional techniques. Moreover, by forming the SD insulating film 60 to be quite thin, sufficient transistor current can be carried and adverse effect on the contact resistance can be prevented. If the thickness of the SD insulating film 60 is made smaller than that of the gate dielectric film 40 and is in a range, for example, from 0.5 nm to 2 nm, the charges can sufficiently tunnel through the SD insulating film 60. Besides, the silicon-silicide interface is higher in resistance than the interior of the silicon and the interior of the silicide as already stated. Due to this, even if the thin SD insulating film 60 is present on the silicon-silicide interface, the influence of the SD insulating film 60 on the contact resistances is small. In this way, the SD insulating film 60 is preferably provided since it can maintain stably low contact resistances of the source layer S and the drain layer D.

According to the first embodiment, the thickness of the silicide layer 51 is almost uniform at whichever location the source layer S or the drain layer D is present. Furthermore, thicknesses of N⁺-type layers (the source layer S and the drain layer D) remaining as silicon crystals are controlled with high accuracy. Therefore, the first embodiment can prevent the silicide layer 51 from becoming excessively thick and penetrating through the BOX layer 20. Conversely, the first embodiment can prevent the silicide layer 51 from becoming excessively thin and inducing the bipolar disturbance. This can ensure uniformity (stability) of characteristics of the memory cells MCs.

An example of a method of writing data to one memory cell MC is described next. To write data “1” to one memory cell MC, the memory cell MC is caused to operate in a saturation state. For example, a voltage of the word line WL connected to the memory cell MC is biased to 1.5 V and that of the bit line BL connected to the memory cell MC is biased to 1.5 V. A voltage of the source layer S is ground GND (0 V). By so setting, impact ionization occurs near the drain layer D and many electron-hole pairs are generated. The electrons generated by the impact ionization flow to the drain layer D whereas the holes generated by the impact ionization are accumulated in the body B having low potential. When balance is held between a current carried if the holes are generated by the impact ionization and a forward current at a pn junction between the body B and the source layer S, a body voltage turns into an equilibrium state. This body voltage is about 0.7 V.

To write data “0” to one memory cell MC, the voltage of the bit line BL is reduced to negative voltage, e.g., −1.5 V. This operation enables a pn junction between the body B and the drain layer D to be largely biased in forward direction. The holes accumulated in the body B are emitted to the drain D and the data “0” is stored in the memory cell MC.

An example of a method of reading data from one memory cell MC is described next. In a data read operation, the word line WL connected to the memory cell MC is activated similarly to a data write operation. However, the bit line BL connected to the memory cell MC is set lower than that in the data write operation. For example, the voltage of the word line WL is set to 1.5 V and that of the bit line BL is set to 0.2 V. The memory cell MC is caused to operate in a linear region. The memory cell MC storing therein data “0” and the memory cell MC storing therein data “1” differ in a threshold voltage of the memory cell MC due to a difference in the number of holes accumulated in the body B. Whether data stored in the memory cell MC is “1” or “0” is discriminated by detecting this threshold voltage difference. The reason for setting the voltage of the bit line BL to low voltage in the data read operation is as follows. If the voltage of the bit line BL is set high to bias the memory cell MC into the saturation state, data “0” is possibly changed to data “1” by the impact ionization if the data “0” is to be read.

A method of manufacturing the FBC memory device according to the first embodiment is described next.

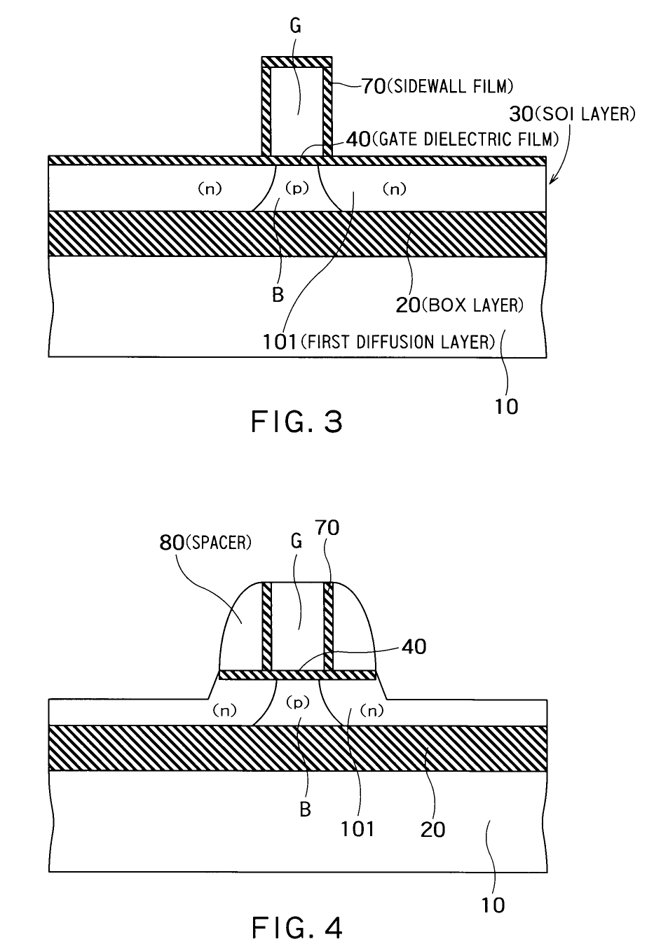

FIGS. 3 to 8 are cross-sectional views showing the method of manufacturing the FBC memory device according to the first embodiment. First, the SOI substrate is prepared. After a surface of the SOI layer 30 is subjected to a pretreatment, the gate dielectric film 40 is formed on the surface of the SOI layer 30 as shown in FIG. 3. Polysilicon is deposited on the gate dielectric film 40. This polysilicon is formed into a gate electrode pattern by lithography and RIE (Reactive Ion Etching). The gate electrode G made of polysilicon is thereby formed.

After forming the thin sidewall film 70 on a side surface of the gate electrode G by thermal oxidation, n-type impurity ions (phosphorus ions or arsenic ions) are implanted into the SOI layer 30 in a self-aligned fashion. An n-type first diffusion layer 101 is thereby formed in the SOI layer 30 as shown in FIG. 3. The first diffusion layer 101 functions as the extension layer EXT when completion of the FBC memory device.

A silicon nitride film is deposited on an entire surface of a structure shown in FIG. 3 by CVD (Chemical Vapor Deposition) or the like. This silicon nitride film is anisotropically etched by the RIE, thereby forming the spacer 80 on the side surface of the gate electrode G across the sidewall film 70. The sidewall film 70 and the spacer 80 will be also referred as “sidewall insulating films 70 and 80”, hereinafter. As shown in FIG. 4, the sidewall insulating films 70 and 80 can be multilayer films including the silicon oxide film and the silicon nitride film. Alternatively, the sidewall insulating films 70 and 80 can be single-layer films of the silicon oxide films or the silicon nitride films. In another alternative, the sidewall insulating films 70 and 80 can be a multilayer film including three layers or more.

In an etching step at which the spacer 80 is formed or in a step next to the etching step, an upper portion of the SOI layer 30 which portion is not covered with the gate electrode G and the sidewall insulating films 70 and 80 is anisotropically etched in a self-aligned fashion by the RIE using the gate electrode G and the sidewall insulating films 70 and 80 as a mask. The thickness TSD of the SOI layer 30 in which the source layer S or the drain layer D is formed can be thereby adjusted. If the thickness TSD is made smaller, the bipolar disturbance can be suppressed more effectively. Note that the gate electrode G is etched simultaneously with the upper portion of the SOI layer 30 in this etching step. Nonetheless, there will be no problem as long as polysilicon is deposited to be thicker by as much as the etching of the gate electrode G.

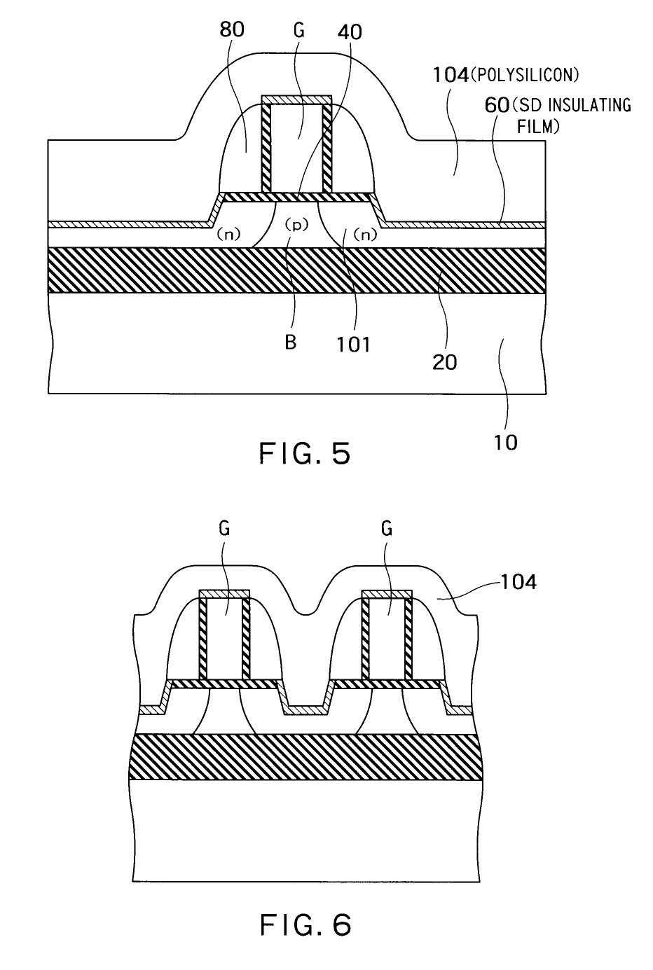

Next, as shown in FIG. 5, the surface of the SOI layer 30 is oxidized thinly, thereby forming the SD insulating film 60. At the same time, a surface of the gate electrode G is oxidized. As shown in FIG. 5, a polysilicon film 104 is then deposited. Normally, a distance between the gate electrodes G of two adjacent memory cells MCs is short as compared with a height of the gate electrode G. That is, an aspect ratio of a trench formed between the gate electrodes G of the two adjacent memory cells MCs is normally high. Therefore, the polysilicon film 104 is formed thick in source and drain formation regions while the polysilicon film 104 is formed thin on the gate electrode G.

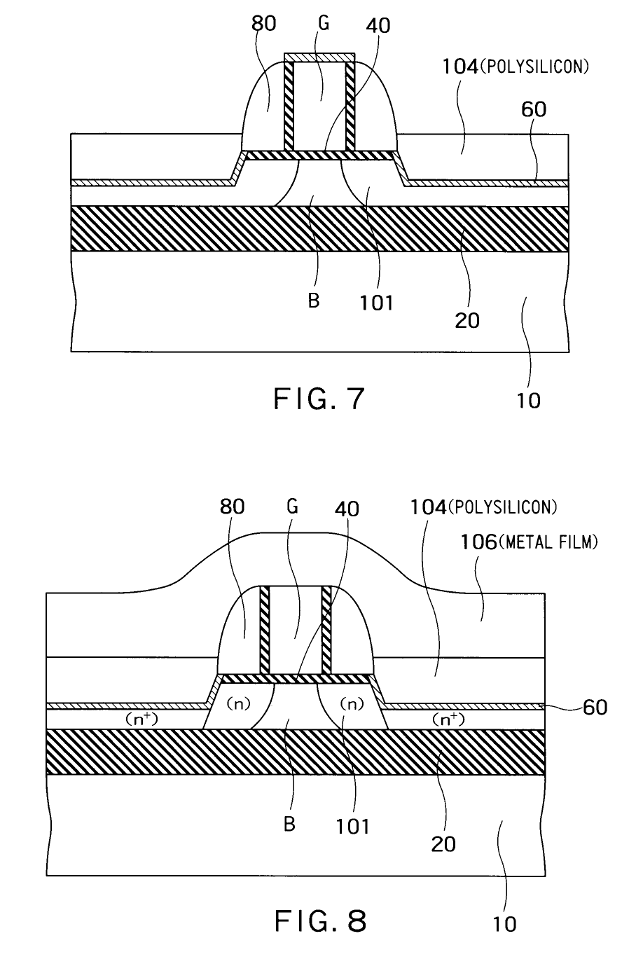

Next, the polysilicon film 104 is etched back. Since the thick polysilicon film 104 is formed in the source and drain formation regions, the polysilicon film 104 is left only in the source and drain formation regions as shown in FIG. 7.

Using the gate electrode G and the sidewall insulating films 70 and 80 as a mask, n-type impurity ions (phosphorus ions or arsenic ions) are implanted into the SOI layer 30. At this time, the n-type impurity ions are implanted not only into the SOI layer 30 in which the source and drain formation regions are formed but also into the polysilicon film 104 present above the source and drain formation regions. After removing the insulating film on an upper surface of the gate electrode G, a metal film 106 is deposited on the gate electrode G and the polysilicon film 104 as shown in FIG. 8. The metal film 106 is made of, for example, nickel. An annealing process is then conducted, thereby siliciding the gate electrode G and the silicon film 104.

Note that the SD insulating film 60 functions as a silicidation stopper to protect silicidation of the source layer S and the drain layer D. By so protecting, even if the entire polysilicon film 104 is sufficiently silicided, the source layer S and the drain layer D are not entirely silicided. As a result, the source layer S and the drain layer D each made of silicon can be formed to be thin and to have uniform thickness.

Thereafter, the barrier film 90, the interlayer dielectric film ILD, the source line contacts SLCs, the bit line contacts BLCs, the source lines SLs, and the bit lines BLs are formed by conventional methods. The FBC memory device shown in FIG. 2 is thereby completed.

The SD insulating film 60 is reduced to some extent in the silicidation step and the subsequent annealing process. Due to this, the thickness of the SD insulating film 60 after completion of the FBC memory device is smaller by about 2 to 3 nm than the initial formation thickness of the SD insulating film 60. Accordingly, the SD insulating film 60 can be formed to be thicker by about 2 to 3 nm than that necessary for the SD insulating film 60 to function as a tunnel film.

The formation method of the SD insulating film 60 is not limited to the thermal oxidation-based method. The SD insulating film 60 can be deposited on the entire surface by such a method as LP (Low-Pressure)-CVD or plasma CVD. Further, the polysilicon film 104 can be made of amorphous silicon or crystalline silicon.

### Modification of First Embodiment

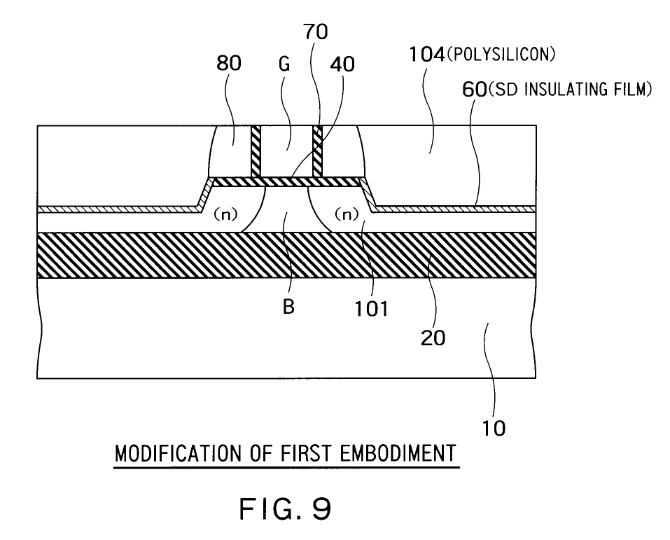

FIG. 9 is a cross-sectional view showing a method of manufacturing an FBC memory device according to a modification of the first embodiment of the present invention. According to the modification of the first embodiment, after the polysilicon film 104 is deposited as shown in FIG. 5 (or FIG. 6), the polysilicon film 104, the gate electrode G, and the sidewall insulating films 70 and 80 are polished by CMP (Chemical Mechanical Polishing). As shown in FIG. 9, the polysilicon film 104, the gate electrode G, and the sidewall insulating films 70 and 80 are thereby flattened. At this time, the surface of the polysilicon film 104 in which the source and drain formation regions are formed acts as a stopper.

Thereafter, as shown in FIG. 8, n-type impurity ions are implanted into the SOI layer 30 so as to form the source layer S and the drain layer D. The metal film 106 are deposited on the polysilicon film 104, the gate electrode G, and the sidewall insulating films 70 and 80. At this time, the metal film 106 is deposited with high coverage of the polysilicon film 104, the gate electrode G, and the sidewall insulating films 70 and 80 since the polysilicon film 104, the gate electrode G, and the sidewall insulating films 70 and 80 are flattened.

Subsequently, through similar steps to those according to the first embodiment, the FBC memory device is completed.

As can be seen, according to the modification of the first embodiment, the metal film 106 with high coverage can be deposited. In the modification of the first embodiment, since the polysilicon 104 and the like are polished by the CMP, the FBC memory device can be manufactured in shorter time than that for manufacturing the FBC memory device according to the first embodiment. Besides, the modification of the first embodiment can attain the same advantages as those of the first embodiment.

### Second Embodiment

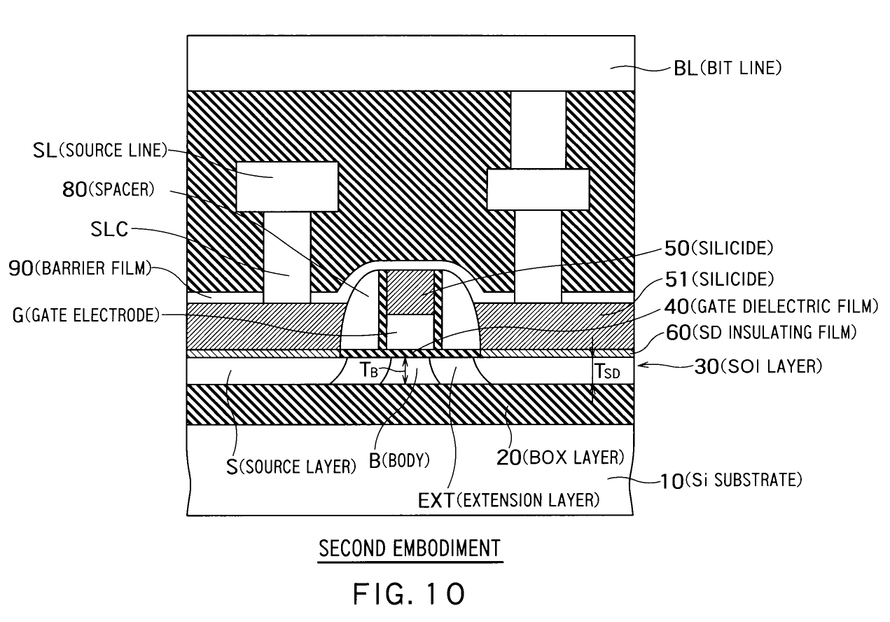

FIG. 10 is a cross-sectional view of an FBC memory device according to a second embodiment of the present invention. In the second embodiment, the thickness TSD of the SOI layer 30 in which the source layer S or the drain layer D is formed is substantially equal to the thickness TB of the SOI layer 30 in which the body B is formed. For example, TSD=TB<10 nm. Other configurations of the FBC memory device according to the second embodiment can be similar to those according to the first embodiment.

If the thickness TSD of the SOI layer 30 is thin enough, the difference in height of the SOI layer 30 described in the first embodiment does not have to be provided. Because the FBC memory device according to the second embodiment does not require etching of the SOI layer 30, its manufacturing time can be shorter than that of the FBC memory device according to the first embodiment. Further, the second embodiment can attain similar advantages to those of the first embodiment.

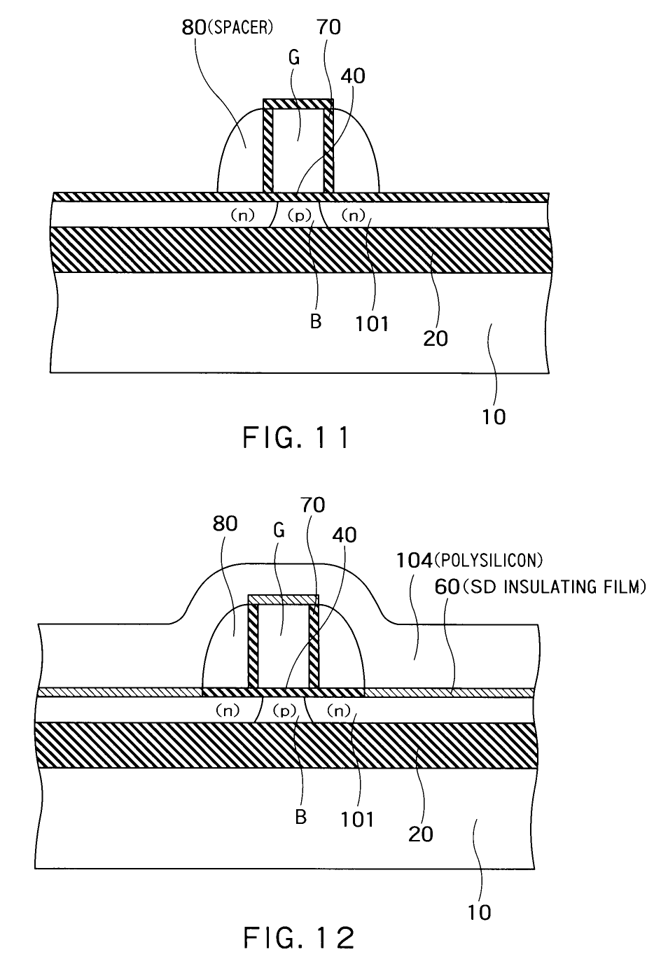

FIGS. 11 and 12 are cross-sectional views showing a method of manufacturing the FBC memory device according to the second embodiment. After the step described with reference to FIG. 3, the spacer 80 is formed as shown in FIG. 11. A method of forming the spacer 80 according to the second embodiment is the same as that described in the first embodiment except that the SOI layer 30 is not etched.

Next, as shown in FIG. 12, the polysilicon film 104 is deposited on the entire surface. Thereafter, through the steps described with reference to FIGS. 5 to 8, the FBC memory device according to the second embodiment is completed. Needless to say, the modification shown in FIG. 9 can be applied to the second embodiment. If the modification is applied to the second embodiment, the thickness (height) of the gate electrode G can be kept large by as much as lack of the difference in height of the SOI layer 30. The modification of the second embodiment can thereby suppress gate resistance from rising.

### Third Embodiment

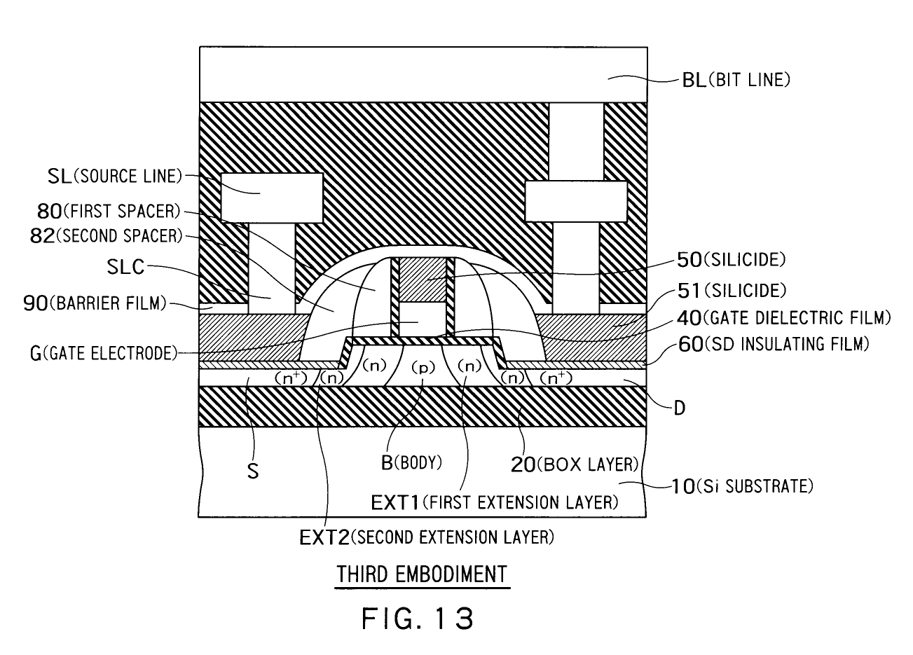

FIG. 13 is a cross-sectional view of an FBC memory device according to a third embodiment of the present invention. The third embodiment differs from the first embodiment in that the FBC memory device includes a second spacer 82 and a second extension layer EXT2. Other configurations of the FBC memory device according to the third embodiment can be similar to those according to the first embodiment. Note that the extension layer EXT in the first embodiment is referred to as “first extension layer EXT1” in the third embodiment.

The second spacer 82 is provided outside of the first spacer 80 with respect to the gate electrode G. The second spacer 82 is provided to form the second extension layer EXT2. The second extension layer EXT2 is formed between the source layer S and the first extension layer EXT1 and between the drain layer D and the first extension layer EXT1. The second extension layer EXT2 is intended to further relax an electric field between the body B and the source layer S and that between the body B and the drain layer D. An impurity concentration of the second extension layer EXT2 is higher than that of the first extension layer EXT1 and lower than those of the source layer S and the drain layer D.

The third embodiment can attain similar advantages to those of the first embodiment.

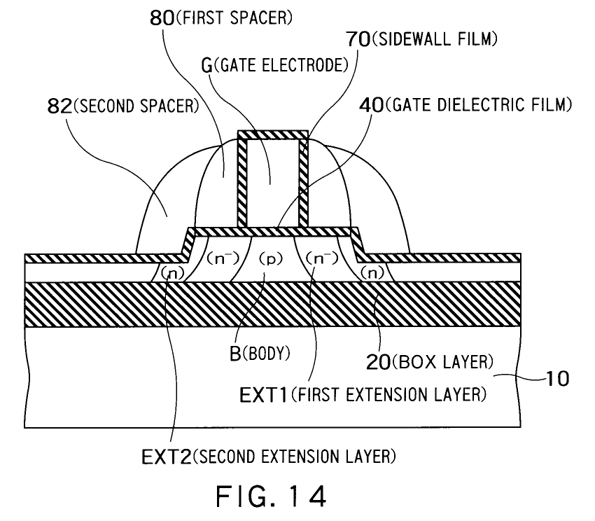

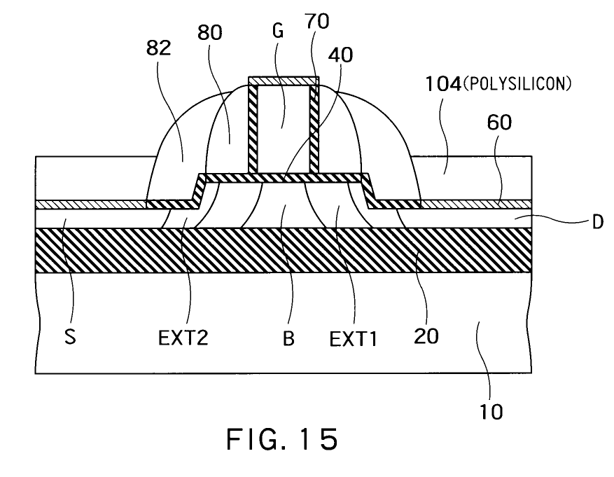

FIGS. 14 and 15 are cross-sectional view showing a method of manufacturing the FBC memory device according to the third embodiment. After obtaining the structure shown in FIG. 4, n-type impurity ions are implanted into the SOI layer 30 using the spacer 80 and the gate electrode G as a mask. At this time, an impurity concentration of the implanted impurity ions is higher than that of the first extension layer EXT1 and lower than those of the source layer S and the drain layer D. The second extension layer EXT2 higher than the first extension layer EXT1 and lower than the source layer S and the drain layer D in impurity concentration is thereby formed as shown in FIG. 13.

Next, the second spacer 82 is formed outside of the first spacer 80 with respect to the gate electrode G. The polysilicon film 104 is deposited on the source and drain formation regions similarly to the first embodiment. A structure shown in FIG. 15 is thereby obtained. Thereafter, through the steps described in the first embodiment, the FBC memory device according to the third embodiment is completed.

Needless to say, the modification of the first embodiment can be applied to the third embodiment.

### Fourth Embodiment

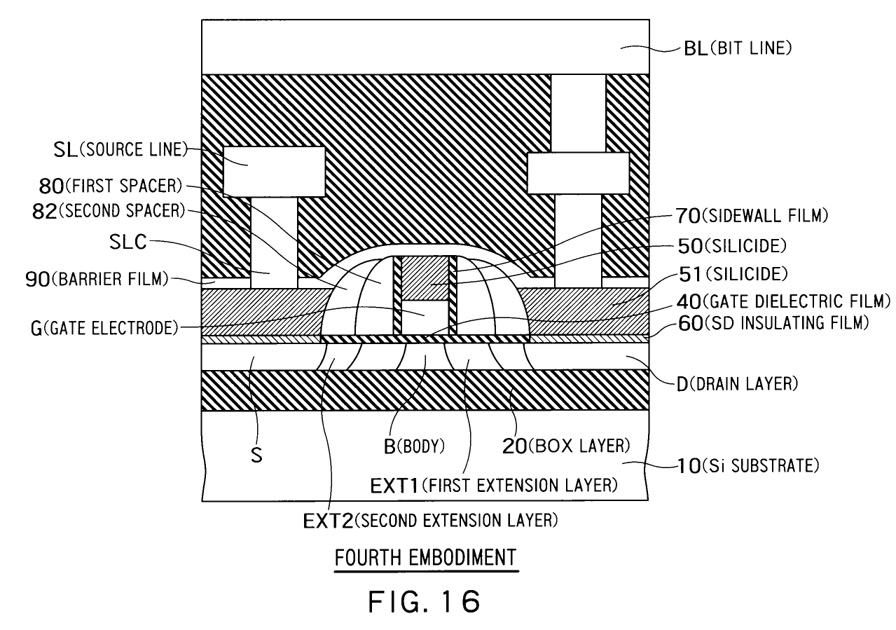

FIG. 16 is a cross-sectional view of an FBC memory device according to a fourth embodiment of the present invention. The fourth embodiment is a combination of the second and third embodiments. Accordingly, in the fourth embodiment, the thickness TSD of the SOI layer 30 in which the source layer S or the drain layer D is formed is substantially equal to the thickness TB of the SOI layer 30 in which the body B is formed. In addition, the FBC memory device according to the fourth embodiment includes the second spacer 82 and the second extension layer EXT2. Other configurations of the FBC memory device according to the fourth embodiment can be similar to those according to the first embodiment. The fourth embodiment can exhibit similar advantages to those of both the second and third embodiments.

A method of manufacturing the FBC memory device according to the fourth embodiment is realized by the manufacturing method according to the third embodiment using the SOI substrate including the thin SOI layer 30 similarly to the second embodiment.

The modification of the first embodiment can be applied to the fourth embodiment. In this case, similarly to the modification of the second embodiment, the thickness (height) of the gate electrode G can be kept large by as much as lack of the difference in height of the SOI layer 30. The modification of the fourth embodiment can thereby suppress gate resistance from rising.

While the n-MISFET is adopted as each memory cell MC in the first to fourth embodiments, a p-MISFET can be adopted as the memory cells MC.

1. A semiconductor memory device comprising:
an insulating film;
a semiconductor layer provided on the insulating film;
a source provided in the semiconductor layer;
a drain provided in the semiconductor layer;
a floating body provided between the source and the drain and being in an electrically floating state, carriers being accumulated in or emitted from the floating body to store data;
a gate dielectric film provided on the floating body;
a gate electrode provided on the gate dielectric film;
a source and drain insulating film provided on the source and the drain, the source and drain insulating film being thinner than the gate dielectric film; and
a silicide layer provided on the source and drain insulating film.

2. The semiconductor memory device according to claim 1, wherein the source and drain insulating film is a tunnel insulating film causing electric charges to tunnel between the source and the silicide on the source and between the drain and the silicide on the drain.

3. The semiconductor memory device according to claim 2, wherein the source and drain insulating film has thickness of 0.5 nm to 2 nm.

4. The semiconductor memory device according to claim 1, wherein a thickness of the semiconductor layer in which the source or the drain is formed is smaller than a thickness of the semiconductor layer in which the floating body is formed.

5. The semiconductor memory device according to claim 2, wherein a thickness of the semiconductor layer in which the source or the drain is formed is smaller than a thickness of the semiconductor layer in which the floating body is formed.

6. The semiconductor memory device according to claim 1, wherein the silicide layer has a substantially uniform thickness.

7. The semiconductor memory device according to claim 1, wherein the source or the drain is shared between a plurality of memory cells adjacent to each other in a source-drain direction, each memory cell including the source, the drain, the floating body, the gate dielectric film, and the gate electrode film.

8. The semiconductor memory device according to claim 2, wherein the source or the drain is shared between a plurality of memory cells adjacent to each other in a source-drain direction, each memory cell including the source, the drain, the floating body, the gate dielectric film, and the gate electrode film.

9. The semiconductor memory device according to claim 4, wherein the source or the drain is shared between a plurality of memory cells adjacent to each other in a source-drain direction, each memory cell including the source, the drain, the floating body, the gate dielectric film, and the gate electrode film.

10. A method of manufacturing a semiconductor memory device comprising:
forming a gate dielectric film on a semiconductor layer provided on an insulating film;
forming a gate electrode on the gate dielectric film;
forming a sidewall insulating film on a side surface of the gate electrode, and forming a source and drain insulating film on a surface of the semiconductor layer not covered with the gate electrode and the sidewall insulating film, the source and drain insulating film being thinner than the gate dielectric film;
depositing a silicon film on the source and drain insulating film;
removing the silicon film on the gate electrode;
depositing a metal film on the silicon film; and
siliciding the silicon film by reacting the silicon film with the metal film.

11. The method of manufacturing a semiconductor memory device according to claim 10, further comprising:
forming a spacer on the side surface of the gate electrode; and
etching an upper portion of the semiconductor layer with the gate electrode and the spacer used as a mask, wherein
the forming of the spacer and the etching of the upper portion of the semiconductor layer are performed after the forming of the gate electrode.

12. The method of manufacturing a semiconductor memory device according to claim 10, wherein the silicide layer has a substantially uniform thickness.

13. The method of manufacturing a semiconductor memory device according to claim 10, wherein the source or the drain is shared between a plurality of memory cells adjacent to each other in a source-drain direction, each memory cell including the source, the drain, the floating body, the gate dielectric film, and the gate electrode film.
